(19) United States
(12) Patent Application Publication
(10) Pub. No.: US 2026/0371716 A1
(43) Pub. Date: Nov. 19, 2026

(54) TRANSISTOR STRUCTURE AND MANUFACTURING METHOD THEREOF

(71) Applicant: Winbond Electronics Corp., Taichung City (TW)

(72) Inventors: Chien-Liang Wu, Tainan City (TW); Shih-Ming Wang, Tainan City (TW); Yi-Hao Chien, Taichung City (TW)

(73) Assignee: Winbond Electronics Corp., Taichung City (TW)

(21) Appl. No.: 19/647,888

(22) Filed: Apr. 15, 2026

(30) Foreign Application Priority Data
May 15, 2025 (TW) 114118322

(51) Int. Cl. H10D 84/83; H10D 30/01; H10D 30/65; H10D 62/10; H10D 62/832; H10D 84/01

(52) U.S. Cl. CPC H10D 84/835; H10D 30/0281; H10D 30/65; H10D 62/124; H10D 62/832; H10D 84/0128; H10D 84/0135; H10D 84/0144; H10D 84/0156; H10D 84/8311; H10D 62/102

(57) ABSTRACT

Provided are a transistor structure and a manufacturing method thereof. The transistor structure includes a first well region, a second well region, a gate structure, a first doped region, a second doped region and a channel layer. The first well region and the second well region are disposed in the substrate, and the second well region is adjacent to the first well region. The gate structure is disposed on the first well region and the second well region. The first doped region is disposed in the first well region and spaced apart from the gate structure. The second doped region is disposed in the second well region and adjacent to the gate structure. The channel layer is disposed in the first well region between the first doped region and the gate structure, and includes a doped first portion and an undoped second portion located on the first portion.

### CROSS-REFERENCE TO RELATED APPLICATION

This application claims the priority benefit of Taiwan application serial no. 114118322, filed on May 15, 2025. The entirety of the above-mentioned patent application is hereby incorporated by reference herein and made a part of this specification.

### BACKGROUND

### Technical Field

The present invention relates to a semiconductor structure and a manufacturing method thereof, and more particularly to a transistor structure and a manufacturing method thereof.

### Description of Related Art

In a general semiconductor apparatus, a high-voltage (HV) transistor can act as a high-voltage switch in a high-voltage switching regulator and a power management integrated circuit (IC). In order to handle the high voltages involved in high voltage applications, the high voltage transistor is expected to have a high breakdown voltage. The lateral diffused metal-oxide-semiconductor (LDMOS) transistor is a high voltage transistor with the above characteristics.

### SUMMARY

The present invention provides a transistor structure and a manufacturing method thereof, in which the channel layer is formed in the substrate between the doped region used as the drain region and the gate structure, and the channel layer is constituted by a doped first portion and an undoped second portion located on the first portion.

The transistor structure of the present invention includes a first well region, a second well region, a first gate structure, a first doped region, a second doped region and a first channel layer. The first well region is disposed in a substrate and has a first conductive type. The second well region is disposed in the substrate and adjacent to the first well region and has a second conductive type opposite to the first conductive type. The first gate structure is disposed on the first well region and the second well region. The first doped region is disposed in the first well region on one side of the first gate structure and spaced apart from the first gate structure. The second doped region is disposed in the second well region on the other side of the first gate structure and adjacent to the first gate structure. The first channel layer is disposed in the first well region between the first doped region and the first gate structure and includes a doped first portion and an undoped second portion, wherein the second portion is located on the first portion.

The manufacturing method of the transistor structure of the present invention includes the following steps. A first well region and a second well region are formed in a substrate, wherein the first well region has a first conductive type, the second well region has a second conductive type opposite to the first conductive type, and the second well region is adjacent to the first well region. A first gate structure is formed on the first well region and the second well region. A first doped region is formed in the first well region on one side of the first gate structure, wherein the first doped region is spaced apart from the first gate structure. A second doped region is formed in the second well region on the other side of the first gate structure, wherein the second doped region is adjacent to the first gate structure. A first channel layer is formed in the first well region between the first doped region and the first gate structure, wherein the first channel layer includes a doped first portion and an undoped second portion, and the second portion is located on the first portion.

Based on the above, in the transistor structure and the manufacturing method thereof of the present invention, the channel layer is constituted by the doped first portion and the undoped second portion located above the first portion, and the channel layer is formed in the substrate between the first doped region used as the drain region and the gate structure. Therefore, the transistor structure of the present invention may have a longer channel length and may effectively improve the breakdown voltage. In addition, there is no need to additionally form a device isolation structure in the substrate between the first doped region used as the drain region and the gate structure. This is beneficial for reducing the size of the transistor structure and enables the transistor structure to have a larger on-current (I_{ON}).

### BRIEF DESCRIPTION OF THE DRAWINGS

FIGS. 1A-1F are cross-sectional schematic diagrams of the manufacturing method of the transistor structure according to the embodiment of the present invention.

### DESCRIPTION OF THE EMBODIMENTS

The transistor structure of the present embodiment can be applied to lateral diffusion metal oxide semiconductor transistors, can effectively improve the break down voltage and scale down device dimension of the transistor, and is suitable for composite metal gate transistors.

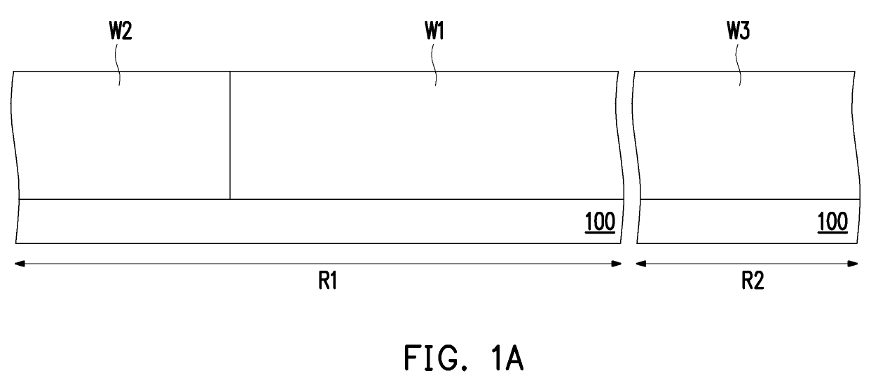

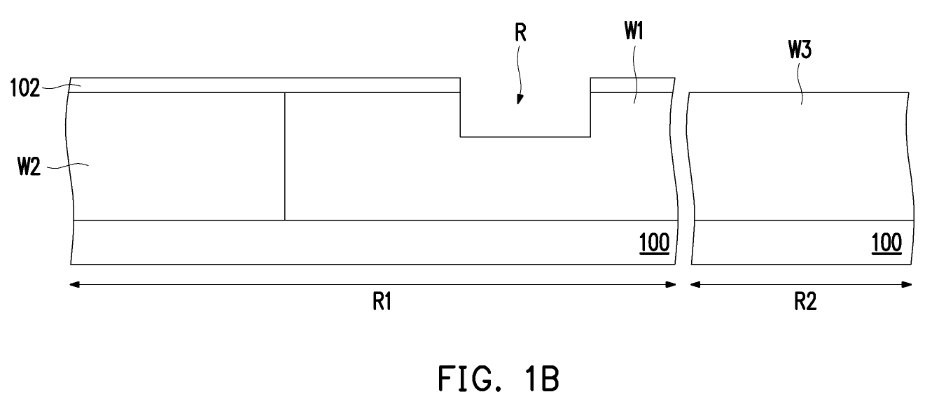

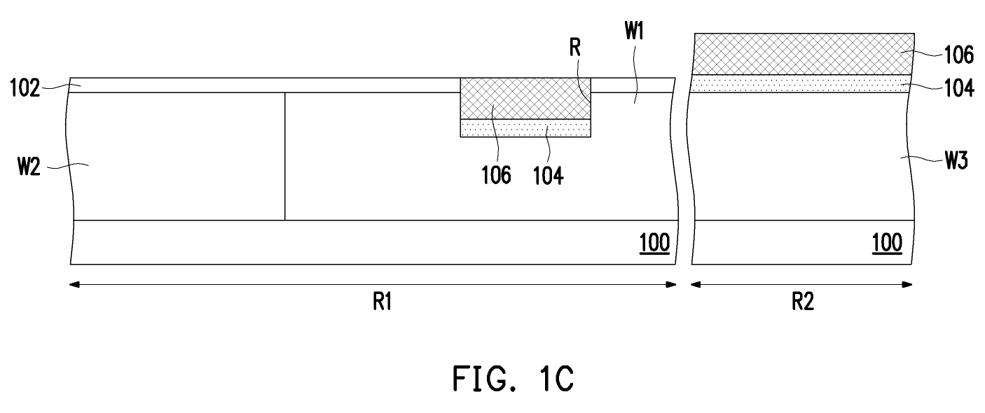

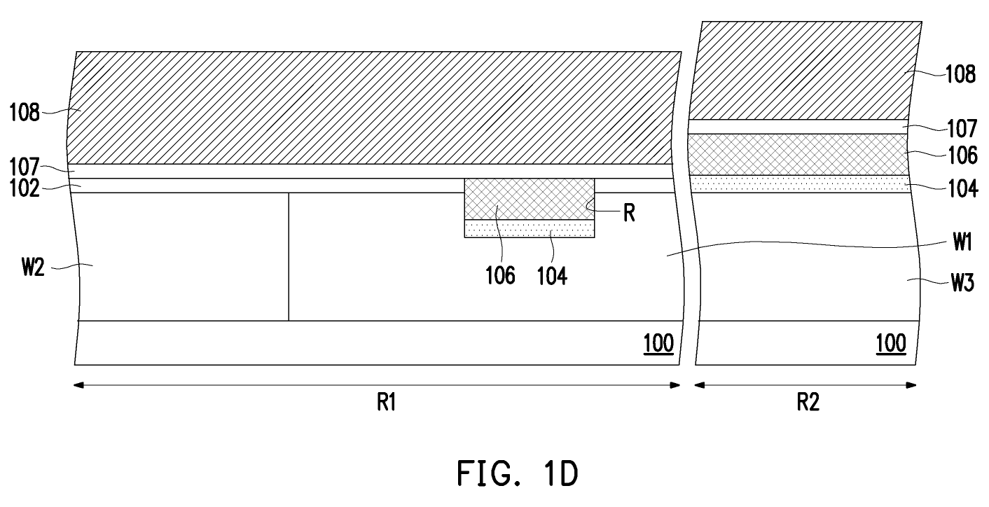

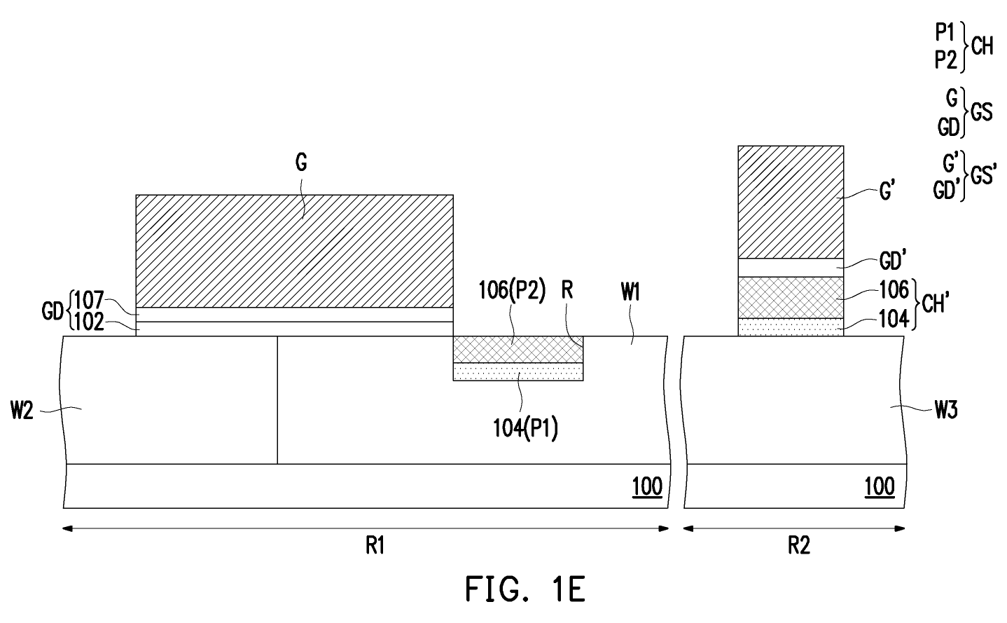

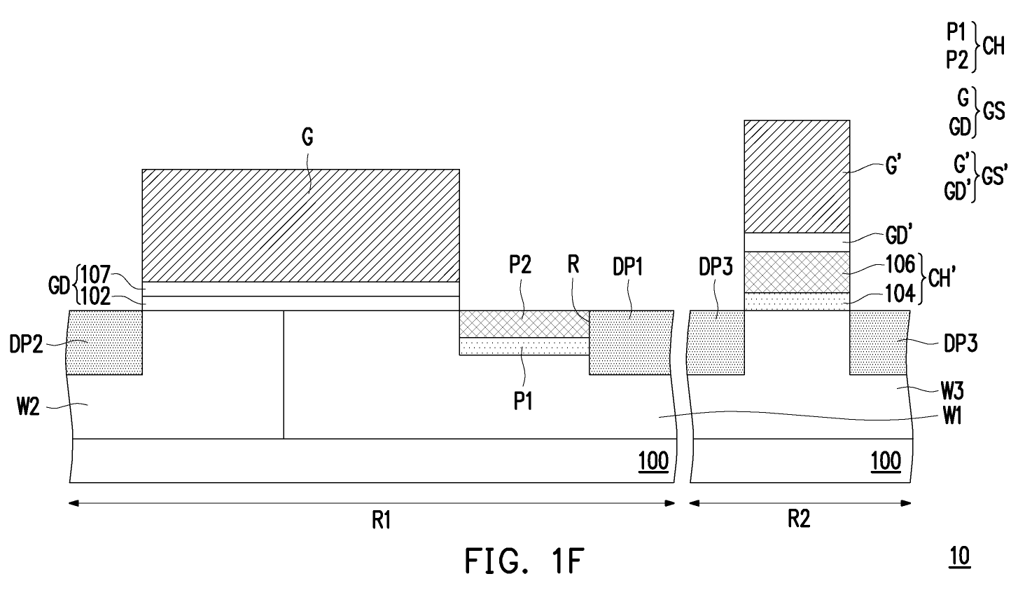

FIGS. 1A-1F are cross-sectional schematic diagrams of the manufacturing method of the transistor structure according to the embodiment of the present invention.

Referring to FIG. 1A, a substrate 100 is provided. In some embodiments, the substrate 100 is a silicon substrate. The substrate 100 may have a first region R1 and a second region R2. Next, a first well region W1 and a second well region W2 are formed in the substrate 100 in the first region R1, and a third well region W3 is formed in the substrate 100 in the second region R2. The first well region W1 is adjacent to the second well region W2. The first well region W1 has a first conductive type, and the second well region W2 has a second conductive type opposite to the first conductive type. The third well region W3 has the second conductive type. The first conductive type may be one of the N-type and the P-type, and the second conductive type may be the other of the N-type and the P-type. In the present embodiment, the first conductivity type is P type as an example for description.

The first well region W1, the second well region W2 and the third well region W3 are formed by, for example, performing the ion implantation process. In addition, in the present embodiment, the first well region W1, the second well region W2 and the third well region W3 have the same depth, that is, the bottom surface of the first well region W1, the bottom surface of the second well region W2 and the bottom surface of the third well region W3 are coplanar.

Referring to FIG. 1B, after forming the first well region W1, the second well region W2 and the third well region W3, a gate dielectric material layer 102 is formed on the substrate 100. The gate dielectric material layer 102 covers the first well region W1, the second well region W2 and the third well region W3. In some embodiments, the material of the gate dielectric material layer 102 is oxide, such as silicon oxide.

Next, a patterning process is performed on the gate dielectric material layer 102 to form an opening in the gate dielectric material layer 102 in the first region R1 and to remove the gate dielectric material layer 102 in the second region R2. The opening exposes a portion of the first well region W1. Afterwards, a portion of the substrate 100 is removed through the opening to form a recess R in the first well region W1. The recess R is used to define the position of the channel layer of the transistor structure of the present embodiment. In the present embodiment, the method for removing a portion of the substrate 100 to form the recess R is, for example, performing an anisotropic etching process using the gate dielectric material layer 102 as the etching mask.

Referring to FIG. 1C, a first channel material layer 104 is formed in the recess R and on the third well region W3. In some embodiments, the material of the first channel material layer 104 is doped silicon germanium (SiGe), so that the first channel material layer 104 has the same first conductive type as the first well region W1. In some embodiments, the first channel material layer 104 may be of P-type. In some embodiments, the dopant in the first channel material layer 104 may be boron (B). The first channel material layer 104 is formed by, for example, performing an epitaxial growth process and in-situ doping the dopant having the first conductive type.

In the first region R1, the formed first channel material layer 104 is located in the lower portion of the recess R. In the present embodiment, the thickness of the first channel material layer 104 is less than half of the depth of the recess R.

After forming the first channel material layer 104, a second channel material layer 106 is formed on the first channel material layer 104. In the first region R1, the second channel material layer 106 fills the recess R. In the present embodiment, in the first region R1, the top surface of the second channel material layer 106 is formed to be coplanar with the top surface of the gate dielectric material layer 102. In some embodiments, the material of the second channel material layer 106 is undoped SiGe. The second channel material layer 106 is formed by, for example, performing an epitaxial growth process. The first channel material layer 104 and the second channel material layer 106 are used to form the channel layer of the transistor structure of the embodiment.

Referring to FIG. 1D, a gate dielectric material layer 107 is formed on the gate dielectric material layer 102 and the second channel material layer 106 in the first region R1 and on the second channel material layer 106 in the second region R2. The material of the gate dielectric material layer 107 is oxide, such as silicon oxide. Then, a gate material layer 108 is formed on the gate dielectric material layer 107. The gate material layer 108 has a high dielectric constant (high-k) metal gate (HKMG) structure. The gate material layer 108 includes a high-k layer and a metal-containing material layer formed thereon. The high-k usually means a dielectric constant greater than 4. The material of the high-k layer is, for example, HfSiO, HfSiON, HfTaO, HfTiO, HfZrO, ZrO₂, Al₂O₃, HfO₂-Al₂O₃ or a combination thereof. The material of the metal-containing material layer is, for example, Al, La, Cu, Ti, Ta, W, Mo, Co, TaN, NiSi, CoSi, TiN, WN, TiAl, TiAlN, TaCN, TaC, TaSiN or a combination thereof. In the present embodiment, in the first region R1, since the top surface of the second channel material layer 106 and the top surface of the gate dielectric material layer 102 are coplanar, it is ensured that the formed gate dielectric material layer 107 and the gate material layer 108 may have a planar surface.

Referring to FIG. 1E, a portion of the gate material layer 108, a portion of the gate dielectric material layer 107, a portion of the gate dielectric material layer 102, a portion of the second channel material layer 106 and a portion of the first channel material layer 104 are removed to expose a portion of the first well region W1, a portion of the second well region W2 and the second channel material layer 106 located in the recess R in the first region R1, and to expose a portion of the third well region W3 in the second region R2. The method for removing a portion of the gate material layer 108, a portion of the gate dielectric material layer 107, a portion of the gate dielectric material layer 102, a portion of the second channel material layer 106 and a portion of the first channel material layer 104 is, for example, performing a patterning process.

In the present embodiment, in the first region R1, after removing a portion of the second channel material layer 106, the remaining second channel material layer 106 and the underlying first channel material layer 104 fill the recess R, and the top surface of the second channel material layer 106 is coplanar with the top surface of the substrate 100. In other embodiments, after removing a portion of the second channel material layer 106, the top surface of the remaining second channel material layer 106 may be higher or lower than the top surface of the substrate 100, as long as the second channel material layer 106 does not contact the metal-containing material layer of the gate material layer 108.

In the first region R1, the first channel material layer 104 and the second channel material layer 106 located in the recess R constitute a channel layer CH of the transistor structure of the present embodiment. In detail, the first channel material layer 104 forms a first portion P1 of the channel layer CH, and the second channel material layer 106 forms a second portion P2 of the channel layer CH. In the present embodiment, the thickness of the second portion P2 is greater than the thickness of the first portion P1. That is, in the present embodiment, in the channel layer CH, a portion including undoped SiGe is located above a portion including doped SiGe and has a relatively large thickness.

In the region R1, after removing a portion of the gate material layer 108, a portion of the gate dielectric material layer 107 and a portion of the gate dielectric material layer 102, the remaining gate material layer 108 constitutes a gate G of the transistor structure of the present embodiment, and the remaining gate dielectric material layer 107 and the gate dielectric material layer 102 constitute a gate dielectric layer GD of the transistor structure of the present embodiment. The gate G and the gate dielectric layer GD constitute a gate structure GS of the transistor structure in the present embodiment. The gate structure GS is formed on the substrate 100 and is located on the first well region W1 and the second well region W2, that is, the gate structure GS partially overlaps with the first well region W1 and partially overlaps with the second well region W2. In addition, the gate structure GS is adjacent to the channel layer CH, that is, a sidewall of the gate structure GS is aligned with a boundary of the channel layer CH that is relatively close to the gate structure GS.

In addition, in the second region R2, after removing a portion of the gate material layer 108, a portion of the gate dielectric material layer 107, a portion of the second channel material layer 106 and a portion of the first channel material layer 104, the remaining gate material layer 108 constitutes a gate G’ of a transistor structure, the remaining gate dielectric material layer 107 constitutes a gate dielectric layer GD’ of the transistor structure, and the remaining first channel material layer 104 and the second channel material layer 106 constitute a channel layer CH’ of the transistor structure. The gate G’ and gate dielectric layer GD’ constitute a gate structure GS’ of the transistor structure.

Referring to FIG. 1F, a first doped region DP1 is formed in the first well region W1 on one side of the gate structure GS, and a second doped region DP2 is formed in the second well region W2 on the other side of the gate structure GS. The first doped region DP1 and the second doped region DP2 have the first conductive type. In addition, the dopant concentration of the first doped region DP1 and the dopant concentration of the second doped region DP2 are greater than the dopant concentration of the first well region W1.

The first doped region DP1 and the second doped region DP2 are formed by, for example, performing an ion implantation process using the gate structure GS and the channel layer CH as the mask. Therefore, the channel layer CH is located between the first doped region DP1 and the gate structure GS, so that the first doped region DP1 is spaced apart from the gate structure GS, and the channel layer CH contacts the first doped region DP1. In addition, the formed second doped region DP2 is adjacent to the gate structure GS, that is, a sidewall of the gate structure GS is aligned with a boundary of the second doped region DP2 that is relatively close to the gate structure GS. In this way, a transistor structure 10 of the present embodiment is formed. In the present embodiment, the first doped region DP1 may be used as a drain region of the transistor structure 10, and the second doped region DP2 may be used as a source region of the transistor structure 10.

In addition, a third doped region DP3 is formed in the third well region W3 on both sides of the gate structure GS’. The third doped regions DP3 have the first conductive type. The third doped regions DP3 may be used as a source region and a drain region of the transistor structure. The third doped regions DP3 are formed by, for example, performing an ion implantation process using the gate structure GS’ and the channel layer CH’ as the mask. The third doped regions DP3, the first doped region DP1 and the second doped region DP2 may be formed in the same step or in different steps. Therefore, in the present embodiment, the transistor structure 10 further comprises an additional transistor, which is composed of the gate structure GS’, the channel layer CH’ and the third doped regions DP3.

In the transistor structure 10, since the channel layer CH is located in the substrate 100 between the first doped region DP1 and the gate structure GS, the first doped region DP1 used as the drain region is separated from the gate structure GS. In addition, the channel layer CH is constituted of the first portion P1 including doped SiGe and the second portion P2 located above the first portion P1 and including undoped SiGe. In this way, the transistor structure 10 may have a longer channel length, and may effectively improve the breakdown voltage of the transistor structure 10.

Furthermore, in the transistor structure 10, the channel layer CH is constituted by the first portion P1 including doped SiGe and the second portion P2 located above the first portion P1 and including undoped SiGe, and the thickness of the second portion P2 is not less than the thickness of the first portion P1. In this way, it may be effectively ensured that the transistor structure 10 has a sufficient channel length. In particular, when the thickness of the second portion P2 is greater than the thickness of the first portion P1, the transistor structure 10 may have a larger I_{ON}, and may effectively avoid leakage current.

In addition, in the transistor structure 10, the first doped region DP1 is spaced apart from the gate structure GS by the channel layer CH, so there is no need to additionally dispose a device isolation structure, such as a shallow trench isolation structure (STI) or an ion implant region, between the first doped region DP1 and the gate structure GS. This is beneficial for reducing the size of the transistor structure and enables the transistor structure to have a larger on-current (I_{ON}).

In the present embodiment, the transistor structure 10 includes the gate G constituted by a HKMG structure and the gate dielectric layer GD constituted by an oxide.

In addition, in the present embodiment, the process steps of the transistor in the first region R1 is integrated with the process steps of the transistor in the second region R2, thus not increasing the complexity of the manufacturing process and effectively reducing the manufacturing cost.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A transistor structure, comprising:
a first well region, disposed in a substrate and having a first conductive type;
a second well region, disposed in the substrate and adjacent to the first well region, and having a second conductive type opposite to the first conductive type;
a first gate structure, disposed on the first well region and the second well region;
a first doped region, disposed in the first well region on one side of the first gate structure and spaced apart from the first gate structure;
a second doped region, disposed in the second well region on the other side of the first gate structure and adjacent to the first gate structure; and
a first channel layer, disposed in the first well region between the first doped region and the first gate structure, and comprising a doped first portion and an undoped second portion, wherein the second portion is located on the first portion.

2. The transistor structure of claim 1, wherein a material of the first portion comprises doped silicon germanium, and a material of the second portion comprises undoped silicon germanium.

3. The transistor structure of claim 1, wherein a thickness of the second portion is not less than a thickness of the first portion.

4. The transistor structure of claim 1, wherein the first gate structure comprises a gate dielectric layer and a gate sequentially disposed on the substrate.

5. The transistor structure of claim 4, the gate has a high dielectric constant metal gate structure.

6. The transistor structure of claim 4, wherein a material of the gate dielectric layer comprises oxide.

7. The transistor structure of claim 1, wherein a top surface of the first channel layer is coplanar with a top surface of the substrate.

8. The transistor structure of claim 1, wherein the first doped region and the second doped region have the first conductive type, and the first portion has the first conductive type.

9. The transistor structure of claim 1, further comprising an additional transistor structure, wherein the additional transistor structure comprises:
a second gate structure, disposed on a third well region in the substrate;
third doped regions, disposed in the third well region on both sides of the second gate structure; and
a second channel layer, disposed between the second gate structure and the third well region.

10. A manufacturing method of a transistor structure, comprising:
forming a first well region and a second well region in a substrate, wherein the first well region has a first conductive type, the second well region has a second conductive type opposite to the first conductive type, and the second well region is adjacent to the first well region;
forming a first gate structure on the first well region and the second well region;
forming a first doped region in the first well region on one side of the first gate structure, wherein the first doped region is spaced apart from the first gate structure;
forming a second doped region in the second well region on the other side of the first gate structure, wherein the second doped region is adjacent to the first gate structure; and
forming a first channel layer in the first well region between the first doped region and the first gate structure, wherein the first channel layer comprises a doped first portion and an undoped second portion, and the second portion is located on the first portion.

11. The manufacturing method of claim 10, wherein a method for forming the first channel layer comprises:
removing a portion of the substrate to form a recess in the first well region;
forming a first channel material layer in the recess; and
forming a second channel material layer on the first channel material layer.

12. The manufacturing method of claim 11, wherein a method for forming the first gate structure comprises:
after forming the first well region and the second well region and before forming the recess, forming a gate dielectric material layer on the substrate;
forming an opening in the gate dielectric material layer to expose a portion of the first well region, wherein the recess is formed by the opening;
after forming the second channel material layer, forming a gate material layer on the gate dielectric material layer and the second channel material layer; and
removing a portion of the gate material layer, a portion of the gate dielectric material layer and a portion of the second channel material layer to define a gate dielectric layer and a gate constituting the first gate structure.

13. The manufacturing method of claim 12, wherein the gate material layer comprises a high dielectric constant layer and a metal-containing material layer located on the high dielectric constant layer.

14. The manufacturing method of claim 12, wherein a material of the gate dielectric material layer comprises oxide.

15. The manufacturing method of claim 12, wherein after removing a portion of the second channel material layer, a top surface of the second channel material layer is coplanar with a top surface of the substrate, and the first channel material layer and a remaining portion of the second channel material layer constitute the first portion and the second portion of the first channel layer, respectively.

16. The manufacturing method of claim 15, wherein a thickness of the second portion is greater than a thickness of the first portion.

17. The manufacturing method of claim 11, wherein a material of the first channel material layer comprises doped silicon germanium, and a material of the second channel material layer comprises undoped silicon germanium.

18. The manufacturing method of claim 17, wherein a method for forming the first channel material layer and the second channel material layer comprises performing an epitaxial growth process.

19. The manufacturing method of claim 10, wherein the first doped region and the second doped region have the first conductive type, and the first portion has the first conductive type.

20. The manufacturing method of claim 10, further comprising forming an additional transistor structure, wherein the additional transistor structure comprises:
a second gate structure, disposed on a third well region in the substrate;
third doped regions, disposed in the third well region on both sides of the second gate structure; and
a second channel layer, disposed between the second gate structure and the third well region.
